(19) United States
(12) Patent Application Publication
(10) Pub. No.: US 2025/0159899 A1
(43) Pub. Date: May 15, 2025

(54) SEMICONDUCTOR MEMORY DEVICE

(71) Applicant: Samsung Electronics Co., Ltd., Suwon-si (KR)

(72) Inventor: HYERAN LEE, Suwon-si (KR)

(21) Appl. No.: 18/944,355

(22) Filed: Nov. 12, 2024

(30) Foreign Application Priority Data
Nov. 13, 2023 (KR) 10-2023-0156323

(51) Int. Cl. H10B 53/20; H10B 53/30

(52) U.S. Cl. CPC H10B 53/20; H10B 53/30

(57) ABSTRACT

A semiconductor memory device including a plurality of semiconductor patterns extending in a first horizontal direction on a substrate and having a first source/drain region, a channel region, and a second source/drain region, at least one interlayer separation insulating layer that separates the plurality of semiconductor patterns from each other in a vertical direction, a plurality of word lines each surrounding the channel region, a bit line connected to the first source/drain region and extending in the vertical direction, a plurality of first electrodes each on one side of the second source/drain region, a plurality of second electrodes each positioned inside respective ones of the plurality of first electrodes, a ferroelectric film positioned between the first electrode and the second electrode, a plate line that contacts the plurality of second electrodes, and a leaker configured to transfer charge between the first electrode and the second electrode.

### CROSS-REFERENCE TO RELATED APPLICATION

This application is based on and claims priority under 35 U.S.C. § 119 to Korean Patent Application No. 10-2023-0156323, filed on Nov. 13, 2023, in the Korean Intellectual Property Office, and the entire contents of the above-identified application are incorporated by reference herein.

### BACKGROUND

The inventive concept relates to semiconductor memory devices, and more particularly, to three-dimensional semiconductor memory devices.

As electronic products become more compact, more multi-functional, and increasingly higher-performance, higher-capacity semiconductor memory devices are increasingly desired. To provide higher-capacity semiconductor memory devices, increased integration is being sought. Since the integration of conventional two-dimensional semiconductor memory devices is mainly determined by the area occupied by unit memory cells, the integration of two-dimensional semiconductor memory devices is increasing but may be limited. Accordingly, three-dimensional semiconductor memory devices have been proposed that increase memory capacity by stacking a plurality of memory cells in a vertical direction on a substrate.

### SUMMARY

The inventive concepts provide a semiconductor memory device having improved operating characteristics by maintaining a constant potential difference between first and second electrodes through a leaker.

The inventive concepts are not limited to that mentioned above, and other inventive concepts may be clearly understood by those skilled in the art from the following description.

To achieve the inventive concepts, semiconductor memory devices are provided.

According to some aspects of the inventive concepts, there is provided a semiconductor memory device. The semiconductor memory device may include a plurality of semiconductor patterns that extend in a first horizontal direction on a substrate and have a first source/drain region, a channel region, and a second source/drain region arranged in the first horizontal direction, at least one interlayer separation insulating layer that separates the plurality of semiconductor patterns from each other in a vertical direction, a plurality of word lines each surrounding the channel region of each of the plurality of semiconductor patterns, a bit line connected to the first source/drain region of each of the plurality of semiconductor patterns and extending in the vertical direction, a plurality of first electrodes each on one side of the second source/drain region of each of the plurality of semiconductor patterns, a plurality of second electrodes each positioned inside respective ones of the plurality of first electrodes, a ferroelectric film positioned between the first electrode and the second electrode, a plate line that contacts the plurality of second electrodes and extends in the vertical direction, and a leaker configured to transfer charge between the first electrode and the second electrode.

According to some aspects of the inventive concepts, there is provided a semiconductor memory device including a plurality of semiconductor patterns extending in a first horizontal direction on a substrate and having a first source/drain region, a channel region, and a second source/drain region arranged in the first horizontal direction, at least one interlayer separation insulating layer that separates the plurality of semiconductor patterns from each other in a vertical direction, a plurality of word lines each surrounding the channel region of each of the plurality of semiconductor patterns, a bit line connected to the first source/drain region of each of the plurality of semiconductor patterns and extending in the vertical direction, a plurality of first electrodes each on one side of the second source/drain region of each of the plurality of semiconductor patterns, a plurality of second electrodes each positioned inside respective ones of the plurality of first electrodes, a ferroelectric film positioned between the first electrode and the second electrode, a plate line that contacts the plurality of second electrodes and extends in the vertical direction, and a leaker configured to transfer charge between the first electrode and the second electrode, wherein the interlayer separation insulating layer is in contact with the plate line in the first horizontal direction, and a cross section of the leaker in a plane is in the shape of a semicircle, and the semicircle has a curvature portion facing the ferroelectric film and a straight portion facing the plate line.

According to some aspects of the inventive concepts, there is provided a semiconductor memory device including a plurality of semiconductor patterns extending in a first horizontal direction on a substrate and having a first source/drain region, a channel region, and a second source/drain region arranged in the first horizontal direction, at least one interlayer separation insulating layer that separates the plurality of semiconductor patterns from each other in a vertical direction, a plurality of word lines each surrounding the channel region of each of the plurality of semiconductor patterns, a gate dielectric film surrounding the word lines, a contact layer connected to the first source/drain region of each of the plurality of semiconductor patterns, a bit line that contacts the contact layer in the first horizontal direction and extends in the vertical direction, a plurality of first electrodes each on one side of the second source/drain region of each of the plurality of semiconductor patterns, a plurality of second electrodes each positioned inside respective ones of the plurality of first electrodes, a ferroelectric film positioned between the first electrode and the second electrode, a plate line that contacts the plurality of second electrodes and extends in the vertical direction, and a leaker configured to transfer charge between the first electrode and the second electrode, wherein the interlayer separation insulating layer is in contact with the plate line in the first horizontal direction, wherein the leaker includes at least one of amorphous silicon, polycrystalline silicon, germanium, chalcogen compound, silicon nitride, or silicon oxide, wherein the leaker is located between the first electrode and the plate line, and an area where the leaker is in contact with the first electrode is greater than an area where the leaker is in contact with the plate line, and wherein a cross section of the leaker in a plane is in the shape of a semicircle.

### BRIEF DESCRIPTION OF THE DRAWINGS

Some examples of embodiments of the present inventive concepts will be more clearly understood from the following detailed description taken in conjunction with the accompanying drawings in which:

FIG. 1 is an equivalent circuit diagram of a cell array of a semiconductor memory device according to some embodiments;

FIG. 2 is a perspective view of a semiconductor memory device according to some embodiments;

FIG. 3 is a cross-sectional view of a semiconductor memory device taken along line A1-A1′ in FIG. 2;

FIG. 4 is a cross-sectional view of a semiconductor memory device taken along line A2-A2′ in FIG. 2;

FIG. 5 is a cross-sectional view of a semiconductor memory device according to some embodiments;

FIGS. 6 to 15 are cross-sectional views schematically showing a method of manufacturing the semiconductor memory device of FIG. 3;

FIGS. 16 to 25 are cross-sectional views schematically showing a method of manufacturing the semiconductor memory device of FIG. 5; and

FIGS. 26 to 35 are cross-sectional views schematically showing a method of manufacturing the semiconductor memory device of FIG. 5.

### DETAILED DESCRIPTION OF THE EMBODIMENTS

Hereinafter, some examples of embodiments of the present inventive concepts are described in detail with reference to the accompanying drawings. The same reference numerals are used for the same components in the drawings, and duplicate descriptions thereof are omitted.

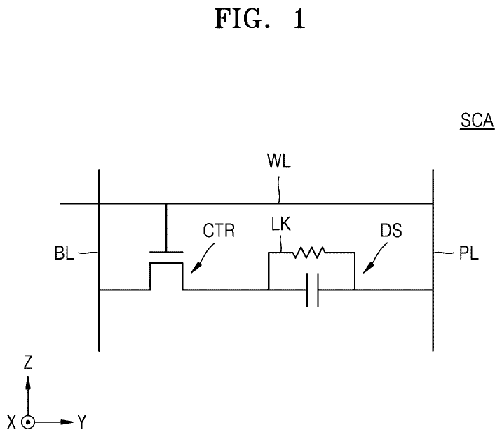

FIG. 1 is an equivalent circuit diagram of a cell array of a semiconductor memory device according to some embodiments.

Referring to FIG. 1, a cell array of a semiconductor memory device may include at least one sub-cell array SCA. The sub-cell array SCA may include at least one bit line BL, at least one word line WL, at least one cell transistor CTR, and at least one data storage element DS. According to some embodiments, one cell transistor CTR may be positioned between one word line WL and one bit line BL, and one data storage element DS may be connected to one cell transistor CTR.

The bit line BL may be a conductive pattern (e.g., a metal line) that is spaced apart from a substrate. The bit line BL may extend in one direction. Hereinafter, the direction in which the bit line BL extends may be understood as a Z-axis direction, and an X-axis direction and a Y-axis direction may be understood as directions perpendicular to each other in a plane having the Z-axis direction as a normal vector. Additionally, in the following drawings, a first horizontal direction, a second horizontal direction, and a vertical direction may be understood as follows: The first horizontal direction may be the X-axis direction, the second horizontal direction may be the Y-axis direction, and the vertical direction may be the Z-axis direction.

When a plurality of bit lines BL are provided in one sub-cell array SCA, the plurality of bit lines BL may be spaced apart from each other in the second horizontal direction Y and may each extend in the vertical direction Z.

The word line WL may be a conductive pattern (e.g., a metal line) that is spaced apart from the substrate. When a plurality of word lines WL are provided in one sub-cell array SCA, the plurality of word lines WL may be spaced apart from each other in the vertical direction Z and may each extend in the second horizontal direction Y.

A gate of the cell transistor CTR may be connected to the word line WL, and a source of the cell transistor CTR may be connected to the bit line BL. A drain of the cell transistor CTR may be connected to a first terminal of the data storage element DS. A second terminal of the data storage element DS may be connected to the plate line PL.

According to some embodiments, the sub-cell array SCA may include one or more semiconductor memory devices that store different logic states. The semiconductor memory device may include, for example, the cell transistor CTR and the data storage element DS. In some embodiments, the semiconductor memory device may be programmable to store two or more logic states. For example, the semiconductor memory device may be configured to store one bit at a time, e.g., logic 0 and logic 1, but the present disclosure is not limited thereto. A single semiconductor memory device (e.g., a multi-level memory cell) may be configured to store more than one bit at a time, e.g., logic 00, logic 01, logic 10, or logic 11.

The semiconductor memory device may store states representing digital data (e.g., the state may be a polarization state of a ferroelectric layer). In a ferroelectric random access memory (FeRAM) architecture, the semiconductor memory device may include the data storage element DS including a ferroelectric material to store charge and/or polarization that is representative of a programmable state.

By activating or selecting the word line WL, the bit line BL, and/or the plate line PL, operations (e.g., read operations and/or write operations) may be performed on the semiconductor memory device. Activating or selecting the word line WL, the bit line BL, or the plate line PL may refer to or may include applying a voltage to each of the lines.

The sub-cell array SCA may include the word line WL, the bit line BL, and the plate line PL which may be arranged in a grid pattern. The semiconductor memory device may be located at the intersection of the word line WL, the bit line BL, and the plate line PL. By applying a voltage to the word line WL, the bit line BL, and the plate line PL, the semiconductor memory device located at the intersection thereof may be selected. In some embodiments, the plate line PL may apply the same voltage to data storage elements DS of a plurality of semiconductor memory devices.

However, while a write operation is being performed on one semiconductor memory device of the sub-cell array SCA, the logic state of the data storage element DS of another semiconductor memory device may be deteriorated or destroyed. For example, in the FeRAM architecture where the semiconductor memory device includes a ferroelectric material, charge may leak from the data storage element DS to the bit line BL, causing the ferroelectric layer of the data storage element DS to become depolarized.

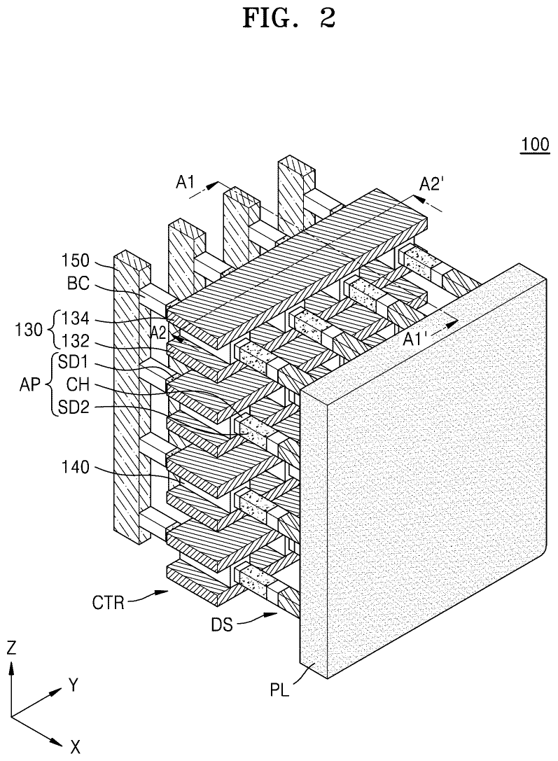

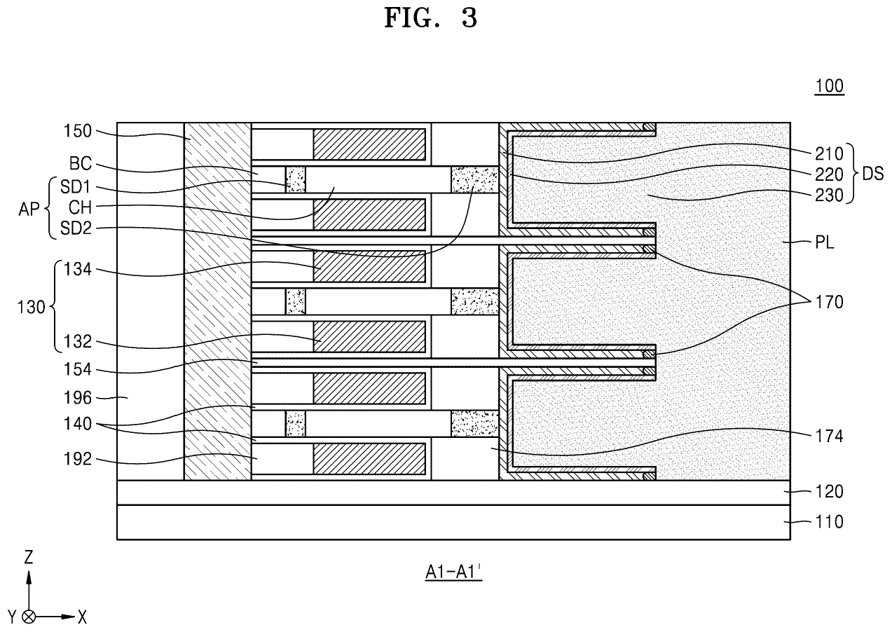

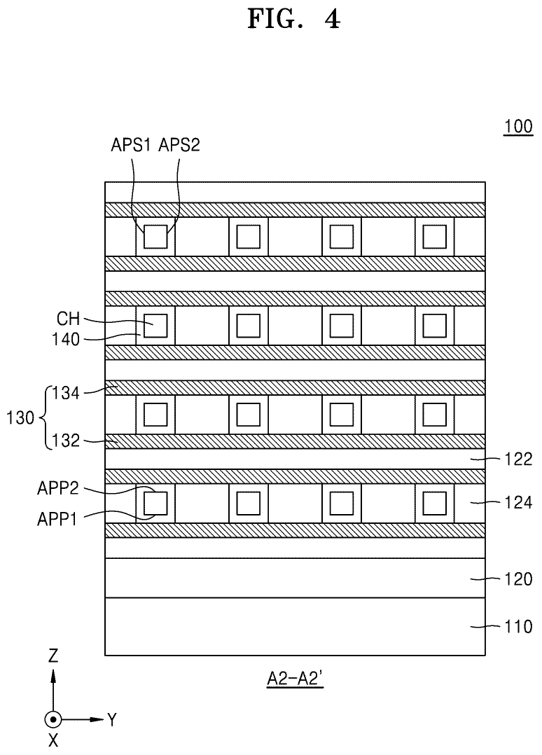

FIG. 2 is a perspective view of a semiconductor memory device according to some embodiments. FIG. 3 is a cross-sectional view of a semiconductor memory device taken along line A1-A1′ in FIG. 2. FIG. 4 is a cross-sectional view of a semiconductor memory device taken along line A2-A2′ in FIG. 2.

Referring to FIGS. 2 to 4, a semiconductor memory device 100 may include a plurality of semiconductor patterns AP, a plurality of bit lines 150, a plurality of word lines 130, and a plurality of data storage elements DS, which may be arranged on a substrate 110.

The substrate 110 may include silicon (Si), for example, crystalline silicon, polycrystalline silicon, or amorphous silicon. In some embodiments, the substrate 110 may include Si, germanium (Ge), or SiGe. In some embodiments, the substrate 110 may include a semiconductor element, such as Ge, or a compound semiconductor, such as silicon carbide (SiC), gallium arsenide (GaAs), indium arsenide (InAs), and indium phosphide (InP). The substrate 110 may have a silicon on insulator (SOI) structure. For example, the substrate 110 may include a buried oxide (BOX) layer. The substrate 110 may include a conductive region, for example, a well doped with impurities or a structure doped with impurities. Additionally, the substrate 110 may have various device separation structures, such as a shallow trench isolation (STI) structure. Although not shown, a peripheral circuit (not shown) and a wiring layer (not shown) connected to the peripheral circuit may be further formed on some areas of the substrate 110. For example, the peripheral circuit may include a planar MOSFET constituting a sub-word line driver, a sense amplifier, etc., but the present disclosure is not limited thereto.

A lower insulating layer 120 may be on the substrate 110, and the lower insulating layer 120 may cover the peripheral circuit and the wiring layer formed on the substrate 110.

The plurality of semiconductor patterns AP may each extend in the first horizontal direction X on the substrate 110 and may be spaced apart from each other in the vertical direction Z. The plurality of semiconductor patterns AP may include, for example, an undoped semiconductor material or a doped semiconductor material. In some embodiments, the plurality of semiconductor patterns AP may include polysilicon. In some embodiments, the plurality of semiconductor patterns AP may include amorphous metal oxide, polycrystalline metal oxide, or a combination of amorphous metal oxide and polycrystalline metal oxide, and, for example, at least one of In—Ga-based oxide (IGO), In—Zn-based oxide (IZO), or In—Ga—Zn-based oxide (IGZO).

The plurality of semiconductor patterns AP may have a line shape or a bar shape that extends in the first horizontal direction X. Each of the semiconductor patterns AP may include a channel region CH, and a first source/drain region SD1 and a second source/drain region SD2 which may be spaced apart from each other in the first horizontal direction X with the channel region CH in between. The first source/drain region SD1 may be connected to the bit line 150, and the second source/drain region SD2 may be connected to the data storage element DS. The first source/drain region SD1 and the second source/drain region SD2 may include a semiconductor material doped with a high concentration of n-type impurities.

According to some embodiments, a bottom surface and a top surface of the channel region CH of the semiconductor pattern AP may be flat and may extend in the first horizontal direction X.

The plurality of word lines 130 may be positioned adjacent to the plurality of semiconductor patterns AP and may extend in the second horizontal direction Y. According to some embodiments, the semiconductor memory device 100 may have a dual gate transistor structure. Each of the plurality of word lines 130 may include a first gate electrode 132 and a second gate electrode 134 respectively arranged on the bottom surface and the top surface of the channel region CH of each of the plurality of semiconductor patterns AP. The plurality of first gate electrodes 132 and the plurality of second gate electrodes 134 may be alternately arranged in the vertical direction Z. According to some embodiments, the first gate electrodes 132 and the second gate electrodes 134 may be flat and may be spaced apart from each other in the vertical direction Z. In some embodiments, the first gate electrode 132 and the second gate electrode 134 may be formed (e.g., integrally formed) to cover the bottom surface and the top surface of the channel region CH.

In some embodiments, the first gate electrode 132 and the second gate electrode 134 may include at least one of doped semiconductor material (doped Si, doped Ge, etc.), conductive metal nitride (titanium nitride, tantalum nitride, etc.), metal (tungsten, titanium, tantalum, etc.), and a metal-semiconductor compound (tungsten silicide, cobalt silicide, titanium silicide, etc.).

According to some embodiments, an interlayer separation insulating layer 154 may be positioned between two of the plurality of word lines 130. The interlayer separation insulating layer 154 may be on top surfaces of a spacer buried layer 174, a first electrode 210, and a gate dielectric film 140 surrounding the second gate electrode 134. According to some embodiments, the interlayer separation insulating layer 154 may overlap with each of the spacer buried layer 174, the first electrode 210, and the gate dielectric film 140 in the vertical direction Z. A plurality of interlayer separation insulating layers 154 may be provided and may be spaced apart from each other in the vertical direction Z. Each of the plurality of interlayer separation insulating layers 154 may be positioned between two adjacent word lines 130 among the plurality of word lines 130. For example, the interlayer separation insulating layer 154 may be positioned between a bottom surface of the first gate electrode 132 of an upper word line 130 of the two adjacent word lines 130 and a top surface of the second gate electrode 134 of a lower word line 130 of the two adjacent word lines 130.

The gate dielectric film 140 may cover the bottom and top surfaces of the word line 130. By the gate dielectric film 140, the first gate electrode 132 may be spaced apart from the semiconductor pattern AP in the vertical direction Z, and the second gate electrode 134 may be spaced apart from the semiconductor pattern AP in the vertical direction Z. The gate dielectric film 140 may surround the semiconductor pattern AP on a Y-Z plane. In this case, portions of the gate dielectric film 140 covering the bottom and top surfaces of the channel region CH may be in contact with the first gate electrode 132 and the second gate electrode 134, and portions of the gate dielectric film 140 covering both sides of the channel region CH in the second horizontal direction Y may not be in contact (e.g., may be not in direct contact) with the first gate electrode 132 or the second gate electrode 134.

According to some embodiments, the gate dielectric film 140 between the first gate electrode 132 and the semiconductor pattern AP may cover one side of the first gate electrode 132 in the first horizontal direction X. A spacer capping layer 192 may be on the other side of the first gate electrode 132 opposite to the one side thereof. Likewise, the gate dielectric film 140 between the second gate electrode 134 and the semiconductor pattern AP may cover one side of the second gate electrode 134 in the first horizontal direction X. The spacer capping layer 192 may be on the other side of the second gate electrode 134 opposite to the one side thereof. Ultimately, a plurality of spacer capping layers 192 may be provided, and each of the plurality of spacer capping layers 192 may be positioned between the bit line 150 and the word line 130. According to some embodiments, the spacer capping layer 192 may include silicon nitride.

In some embodiments, the gate dielectric film 140 covering the bottom and top surfaces of the channel region CH may extend in the second horizontal direction Y and may not cover both sides of the channel region CH in the second horizontal direction Y.

In some embodiments, the gate dielectric film 140 may include at least one selected from a high-k dielectric material having a higher dielectric constant than silicon oxide and a ferroelectric material. In some embodiments, the gate dielectric film 140 may include at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAIO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO).

The plurality of bit lines 150 may extend in the vertical direction Z on the substrate 110 and may be spaced apart from each other in the second horizontal direction Y. The plurality of bit lines 150 may include one of a doped semiconductor material, a conductive metal nitride, a metal, and a metal-semiconductor compound. A buried insulating layer 196 may cover one end of the bit line 150 and may extend in the vertical direction Z. According to some embodiments, the buried insulating layer 196 may include silicon oxide.

Each of contact layers BC may be positioned between the plurality of bit lines 150 and the plurality of semiconductor patterns AP connected thereto. The contact layer BC may be positioned between the semiconductor pattern AP and the bit line 150. The contact layer BC may include a metal silicide material and may include, for example, at least one of titanium silicide, tungsten silicide, cobalt silicide, and nickel silicide.

The data storage element DS may include the first electrode 210, a ferroelectric film 220, and a second electrode 230 arranged (e.g., sequentially arranged with the ferroelectric film 220 between the first electrode 210 and the second electrode 230) in the first horizontal direction X. A plurality of data storage elements DS may be provided and may be spaced apart from each other in the vertical direction Z. Each of the plurality of data storage elements DS may be connected to a plate line PL.

The data storage element DS may be connected to the semiconductor pattern AP in the first horizontal direction X. Specifically, the first electrode 210 of the data storage element DS may be connected to the second source/drain region SD2 of the semiconductor pattern AP. Although not shown, an additional contact layer (not shown) may be formed between the first electrode 210 and the second source/drain region SD2.

In some embodiments, the first electrode 210 and the second electrode 230 may include doped semiconductor material, conductive metal nitride, such as titanium nitride, tantalum nitride, niobium nitride, or tungsten nitride, metal, such as ruthenium, iridium, titanium or tantalum, and conductive metal oxide, such as iridium oxide or niobium oxide.

In some embodiments, a cross-section of the first electrode 210 in the X-Z plane may have a “⊏” shape. A portion of the first electrode 210 that extends in the vertical direction Z may be in contact with the second source/drain region SD2 and the spacer buried layer 174 in the first horizontal direction X. Portions of the first electrode 210 that extend in the first horizontal direction X may be positioned at the top and at the bottom thereof, respectively, and at least one of the portions thereof that extend in the first horizontal direction X may be in contact with the interlayer separation insulating layer 154 in the vertical direction Z.

A top surface and a bottom surface of the second electrode 230 may be surrounded by the first electrode 210, and one side of the second electrode 230 adjacent to the second source/drain region SD2, among both sides thereof in the first horizontal direction X, may also be surrounded by the first electrode 210. The other side of the two sides of the second electrode 230 in the first horizontal direction X may be in contact with the plate line PL in the first horizontal direction X.

The ferroelectric film 220 may be positioned between the first electrode 210 and the second electrode 230. The ferroelectric film 220 may include a ferroelectric material. For example, the ferroelectric film 220 may include hafnium (Hf)-based oxide. Specifically, the Hf-based oxide may include HfO, HfSiO, HfON, and HfSiON. When the ferroelectric film 220 includes Hf-based oxide, the ferroelectric film 220 may include at least one dopant of zirconium (Zr), Si, aluminum (Al), yttrium (Y), gadolinium (Gd), lanthanum (La), scandium (Sc), and strontium (Sr). However, the material of the ferroelectric film 220 is not limited to the materials described above.

The ferroelectric film 220 may include a single film or a multi-film. When the ferroelectric film 220 includes a multi-film, first and second outermost sides thereof may include a ferroelectric thin film. As a specific example, the ferroelectric film 220 may have a triple-film structure consisting of a first ferroelectric thin film, an AlO thin film, and a second ferroelectric thin film. Additionally, the ferroelectric film 220 may have a quint-film structure consisting of a first ferroelectric thin film, a first AlO thin film, a second ferroelectric thin film, a second AlO thin film, and a third ferroelectric thin film. However, the multi-film structure of the ferroelectric film 220 is not limited to the triple-film or quint-film structure.

A side of the interlayer separation insulating layer 154 in the first horizontal direction X may protrude or extend further in the first horizontal direction X than a side of the spacer buried layer 174 in the first horizontal direction X. Each of the top and bottom surfaces of the interlayer separation insulating layer 154 protruding in the first horizontal direction X may be in contact with the first electrode 210 in the vertical direction Z. According to some embodiments, the interlayer separation insulating layer 154 may be in contact with the plate line PL in the first horizontal direction X. The ferroelectric film 220 may not be positioned between (e.g., may not be between) the interlayer separation insulating layer 154 and the plate line PL. The interlayer separation insulating layer 154 may protrude or extend further in the first horizontal direction X than the spacer buried layer 174.

The first electrode 210 may be connected to the plate line PL through a leaker 170. The leaker 170 may be positioned between the first electrode 210 and the plate line PL. Specifically, the leaker 170 may be formed at an end of a first horizontal direction X side of the first electrode 210 that extends in the first horizontal direction X. The leaker 170 may be in contact with each of the first electrode 210 and the plate line PL in the first horizontal direction X. According to some embodiments, two leakers 170 may be provided to one first electrode 210. For example, the leakers 170 may be provided to portions of the first electrode 210 extending in the first horizontal direction X, respectively.

A cross-section of the leaker 170 in the X-Z plane may be in the shape of a semicircle. According to some embodiments, the semicircle may have a curvature in a portion adjacent to the first electrode 210 and may have no curvature in a portion adjacent to the plate line PL. For example, a circular portion of the semicircle may face the first electrode 210. According to some embodiments, another cross-section of the leaker 170 in the X-Z plane may be in the shape of a semi-ellipse. Herein, the semicircle may include a semi-ellipse. In other words, the semicircle includes the semi-ellipse and may have a broader meaning. According to some embodiments, an area where the leaker 170 is in contact with the first electrode 210 may be greater than an area where the leaker 170 is in contact with the plate line PL. According to some embodiments, the leaker 170 may have relatively low resistance characteristics at relatively low voltages and may have relatively high resistance characteristics at relatively high voltages.

The leaker 170 may include at least one of amorphous silicon, polycrystalline silicon, Ge, chalcogenide, silicon nitride, and silicon oxide. In addition, the leaker 170 may include an insulator doped with at least one metal selected from titanium (Ti), tantalum (Ta), niobium (Nb), molybdenum (Mo), strontium (Sr), Y, chromium (Cr), Hf, Zr, meitnerium (W), and La.

The plate line PL may be placed at one end of the data storage element DS. The plate line PL may extend in the vertical direction Z and the second horizontal direction Y. The plate line PL may be in contact with the plurality of second electrodes 230. In some embodiments, the plurality of second electrodes 230 and the plate line PL may be formed (e.g., integrally formed) and may be understood as one electrode. Additionally, in some embodiments, the interlayer separation insulating layer 154 may extend in the first horizontal direction X so that the plate line PL may be separated in the vertical direction Z.

In FIGS. 2 to 4, it is illustrated that the height of one data storage element DS in the vertical direction Z is equal to the height of one semiconductor pattern AP in the vertical direction Z, and the width of one data storage element DS in the second horizontal direction Y is equal to the width of one semiconductor pattern AP in the second horizontal direction Y. However, in some embodiments, the height of one data storage element DS in the vertical direction Z may be greater than the height of one semiconductor pattern AP in the vertical direction Z, or the width of one data storage element DS in the second horizontal direction Y may be greater than the width of one semiconductor pattern AP in the second horizontal direction Y.

In the semiconductor memory device 100 according to some inventive concepts of the present disclosure, as the first electrode 210 is connected to the plate line PL by the leaker 170, a potential difference between the first electrode 210 and the second electrode 230 may be maintained relatively constant. Depending on the operation of the semiconductor memory device 100, charge may leak from at least one of the first electrode 210 and the second electrode 230. For example, charge may leak from the data storage element DS to the bit line 150 when the logic state of the data storage element DS of the other semiconductor memory device 100 is deteriorated or destroyed while a write operation of the semiconductor memory device 100 is performed. When the potential difference between the first electrode 210 and the second electrode 230 occurs due to the charge leakage, charge may move from a high potential to a low potential through the leaker 170 connecting the first electrode 210 to the plate line PL, thereby eliminating the potential difference between the first electrode 210 and the second electrode 230. As a result, the potential difference between the first electrode 210 and the second electrode 230 may be maintained relatively constant by the leaker 170 in the semiconductor memory device 100, thereby preventing the ferroelectric material included in the ferroelectric film 220 from being depolarized.

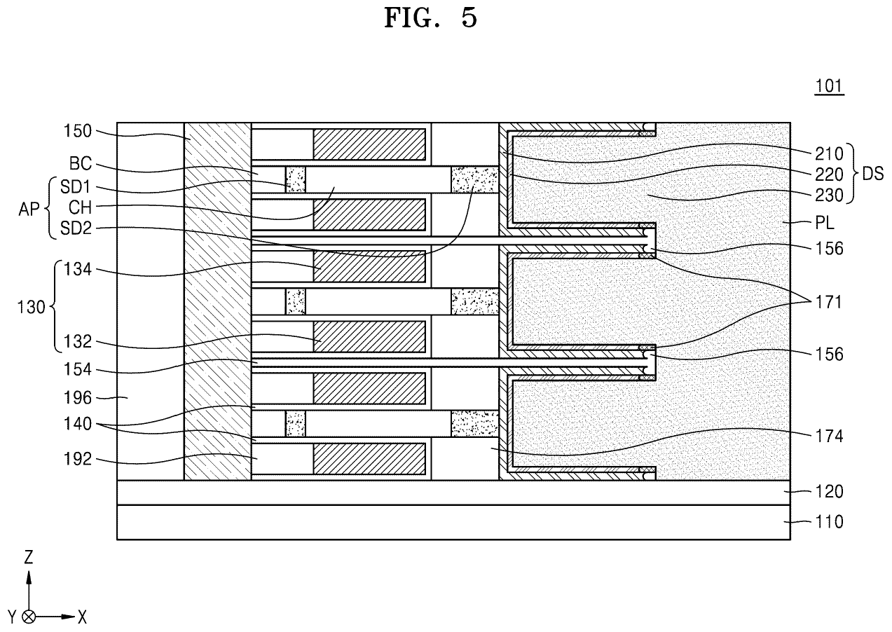

FIG. 5 is a cross-sectional view of a semiconductor memory device according to some embodiments. Hereinafter, substantial description that is substantially the same between the semiconductor memory device 100 of FIG. 4 and a semiconductor memory device 101 of FIG. 5 may be omitted and only the differences therebetween may be mainly described in the interest of brevity.

Referring to FIG. 5, the semiconductor memory device 101 may include a substrate 110, a lower insulating layer 120, a semiconductor pattern AP, a word line 130, a bit line 150, a buried insulating layer 196, a gate dielectric film 140, an interlayer separation insulating layer 154, an electrode separation insulating layer 156, a data storage element DS, a leaker 171, and a plate line PL.

According to some embodiments, the data storage element DS may include a first electrode 210, a ferroelectric film 220, and a second electrode 230. A plurality of data storage elements DS may be provided and may be spaced apart from each other in the vertical direction Z. The plurality of data storage elements DS may be spaced apart from each other in the vertical direction Z by the interlayer separation insulating layers 154. The electrode separation insulating layer 156 may be provided on each of upper and lower ends of the interlayer separation insulating layer 154. The electrode separation insulating layer 156 may be positioned between the first electrode 210 and the plate line PL. Specifically, the electrode separation insulating layer 156 may be positioned between the plate line PL and an end of a portion of the first electrode 210 which extends in the first horizontal direction X.

According to some embodiments, a cross-section of the electrode separation insulating layer 156 in the X-Z plane may have a shape of a semicircle. According to some embodiments, the semicircle may have a curvature in a portion adjacent to the first electrode 210 and may have no curvature in a portion adjacent to the plate line PL. For example, a circular portion of the semicircle may face the first electrode 210. According to some embodiments, a cross-section of the electrode separation insulating layer 156 in the X-Z plane may have a semi-elliptical shape. The electrode separation insulating layer 156 may be in contact with the first electrode 210 in the first horizontal direction X, may be in contact with the plate line PL in the first horizontal direction X, may be in contact with the interlayer separation insulating layer 154 in the vertical direction Z, and may be in contact with the leaker 171 in the vertical direction Z.

The leaker 171 may be formed at one end of the ferroelectric film 220. The leaker 171 may be positioned between the ferroelectric film 220 and the plate line PL. Specifically, the leaker 171 may be formed at one end of a portion of the ferroelectric film 220 which extends in the first horizontal direction X. The leaker 171 may be arranged to contact the first electrode 210 in the vertical direction Z, to contact the plate line PL in the first horizontal direction X, and to contact the second electrode 230 in the vertical direction Z. The leaker 171 may be in contact with the electrode separation insulating layer 156 in the vertical direction Z. According to some embodiments, a cross-section of the leaker 171 in the X-Z plane may be in the shape of a semi-ellipse. The semi-ellipse may be arranged so that a curvature portion thereof faces the ferroelectric film 220. According to some embodiments, the sum of an area where the leaker 171 is in contact with the second electrode 230 and an area where the leaker 171 is in contact with the plate line PL may be greater than an area where the leaker 171 is in contact with the first electrode 210.

In the semiconductor memory device 101 according to some inventive concepts of the present disclosure, the potential difference between the first electrode 210 and the second electrode 230 may be maintained relatively constant by the leaker 171 connecting the first electrode 210 to the second electrode 230 and connecting the first electrode 210 to the plate line PL.

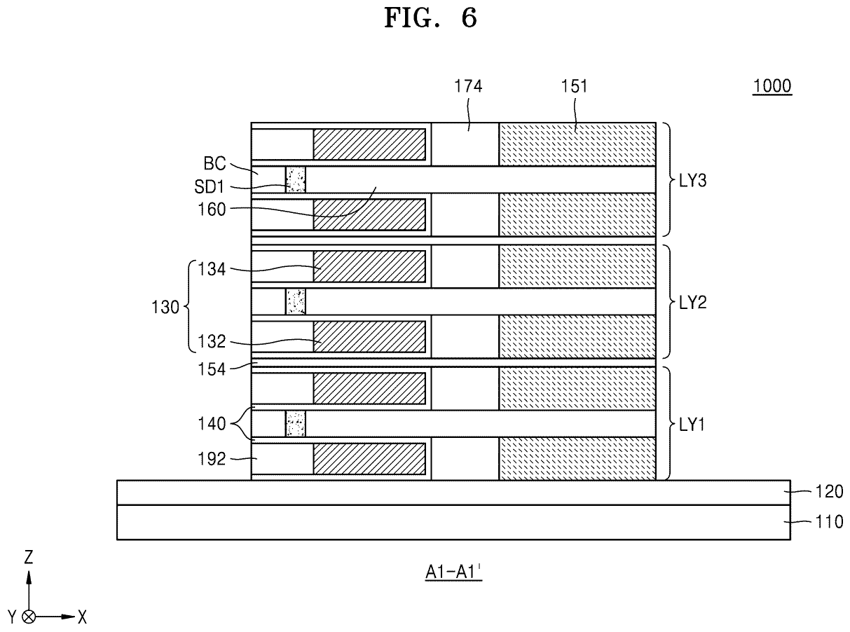

FIGS. 6 to 15 are cross-sectional views schematically showing a method of manufacturing the semiconductor memory device of FIG. 3. Hereinafter, description that is substantially the same as that given with reference to FIGS. 2 to 4 is omitted and the differences therebetween are mainly described in the interest of brevity.

Referring to FIG. 6, a stacked structure 1000 is provided. The stacked structure 1000 may include a substrate 110 and a lower insulating layer 120 stacked on the substrate 110. A plurality of layers LY1, LY2, and LY3 may be formed on the lower insulating layer 120 of the stacked structure 1000. Herein, a first layer LY1, a second layer LY2, and a third layer LY3 are formed on the lower insulating layer 120 but the present disclosure not limited thereto. Two layers or four layers or more may be formed on the lower insulating layer 120.

The plurality of layers LY1, LY2, and LY3 may be separated from each other by interlayer separation insulating layers 154. For example, an interlayer separation insulating layer 154 (e.g., a first interlayer separation insulating layer 154) may be located between the first layer LY1 and the second layer LY2, and another interlayer separation insulating layer 154 (e.g., a second interlayer separation insulating layer 154) may be located between the second layer LY2 and the third layer LY3.

Each of the first layer LY1, the second layer LY2, and the third layer LY3 may include a single crystal bar 160, a first source/drain region SD1 formed on one side of the single crystal bar 160, and a contact layer BC spaced apart from the single crystal bar 160 in the first horizontal direction X with the first source/drain region SD1 in between.

The single crystal bar 160 may extend in the first horizontal direction X and may have a bar shape having substantially the same thickness in the vertical direction Z. According to some embodiments, the single crystal bar 160 may include a material having the same or similar etching characteristics as the substrate 110, or may include the same material as the substrate 110. In some embodiments, the single crystal bar 160 may include single crystal Si. In some embodiments, the single crystal bar 160 may include a single crystal 2D material semiconductor or a single crystal oxide semiconductor material. For example, the 2D material semiconductor may include MoS₂, WSe₂, graphene, carbon nanotubes, or a combination thereof. For example, the oxide semiconductor material may include InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO, or InxGayO, or a combination of two or more thereof. For example, the single crystal bar 160 may include a single layer or layers of the oxide semiconductor material. In some embodiments, the single crystal bar 160 may include a material having a bandgap energy greater than that of Si.

According to some embodiments, the single crystal bar 160 may be formed through a chemical vapor deposition (CVD) process, a plasma enhanced CVD (PECVD) process, or an atomic layer deposition (ALD) process.

The first source/drain region SD1 may be formed by injecting impurities into one end of the single crystal bar 160. After forming the first source/drain region SD1, the contact layer BC surrounding a sidewall of the first source/drain region SD1 may be formed. One sidewall of the first source/drain region SD1 may be covered by the contact layer BC.

Each of the first layer LY1, the second layer LY2, and the third layer LY3, may include a first sacrificial layer 151, a spacer buried layer 174, a word line 130, a spacer capping layer 192, and a gate dielectric film 140 formed on each of the top and the bottom of the single crystal bar 160.

The word line 130 may surround the single crystal bar 160. The gate dielectric film 140 may be located between the word line 130 and the single crystal bar 160. The gate dielectric film 140 may surround the word line 130 and the spacer capping layer 192. One side of the spacer capping layer 192 may be exposed from the gate dielectric film 140 in the first horizontal direction X. The spacer capping layer 192 may include silicon nitride.

The spacer buried layer 174 may be located between the first sacrificial layer 151 and the word line 130. The spacer buried layer 174 may include one of silicon oxide, a silicon oxynitride film, a carbon-containing silicon oxide film, a carbon-containing silicon nitride film, and a carbon-containing silicon oxynitride film. The first sacrificial layer 151 may be spaced apart from the word line 130 in the first horizontal direction X with the spacer buried layer 174 in between. One side of the first sacrificial layer 151 may be exposed in the first horizontal direction X.

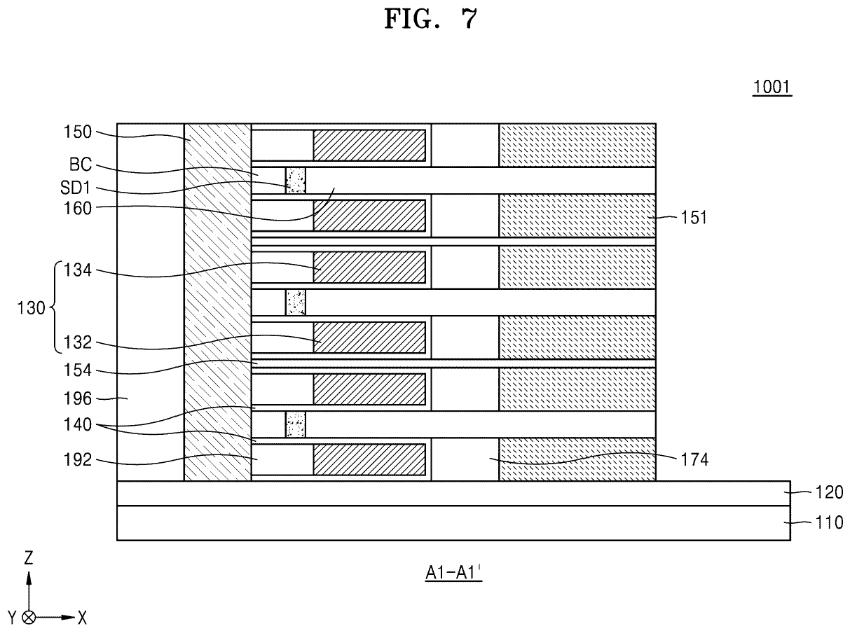

Referring to FIG. 7, a stacked structure 1001 may be formed by forming the bit line 150 extending in the vertical direction Z on the lower insulation layer 120 in the stacked structure 1000 of FIG. 6 and contacting the plurality of contact layers BC and spacer capping layers 192 in the first horizontal direction X, and forming the buried insulating layer 196 covering the bit line 150. The bit line 150 may be formed by filling a through hole that contacts the contact layer BC and extends in the vertical direction Z. The bit line 150 may include one of doped semiconductor material, such as Si doped with impurities and Ge doped with impurities, conductive metal nitride, such as titanium nitride and tantalum nitride, metal, such as tungsten, titanium, and tantalum, and a metal-semiconductor compound, such as tungsten silicide, cobalt silicide, titanium silicide, or the like.

The buried insulating layer 196 covering one side of the bit line 150 may be formed. The buried insulating layer 196 may include silicon oxide. The buried insulating layer 196 may extend in the vertical direction Z.

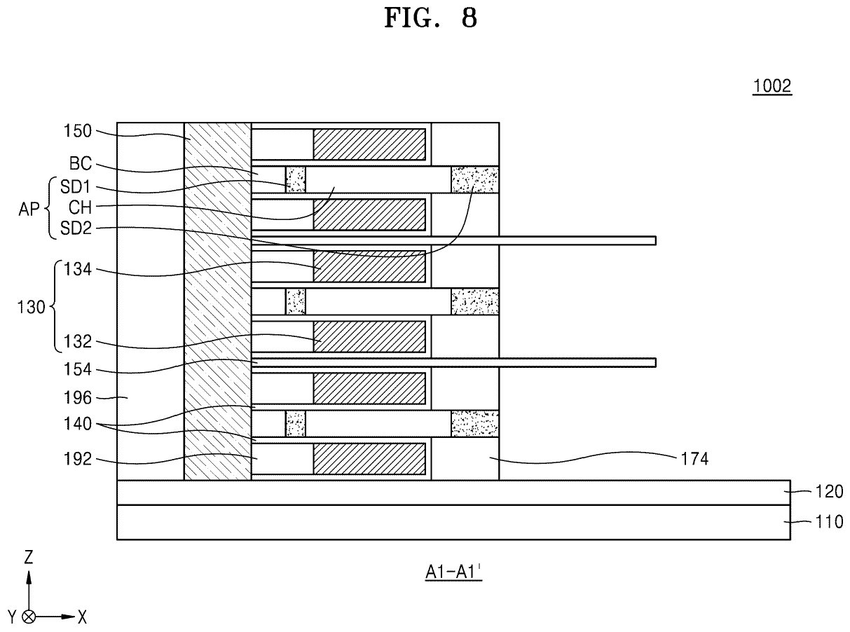

Referring to FIG. 8, a stacked structure 1002 may be formed by removing the first sacrificial layer 151 from the stacked structure 1001 of FIG. 7, etching a portion of the single crystal bar 160, and doping one side of the remaining portion of the single crystal bar 160 with impurities to form the second source/drain region SD2. The interlayer separation insulating layer 154 may protrude or extend further in the first horizontal direction X than the spacer buried layer 174 and the second source/drain region SD2.

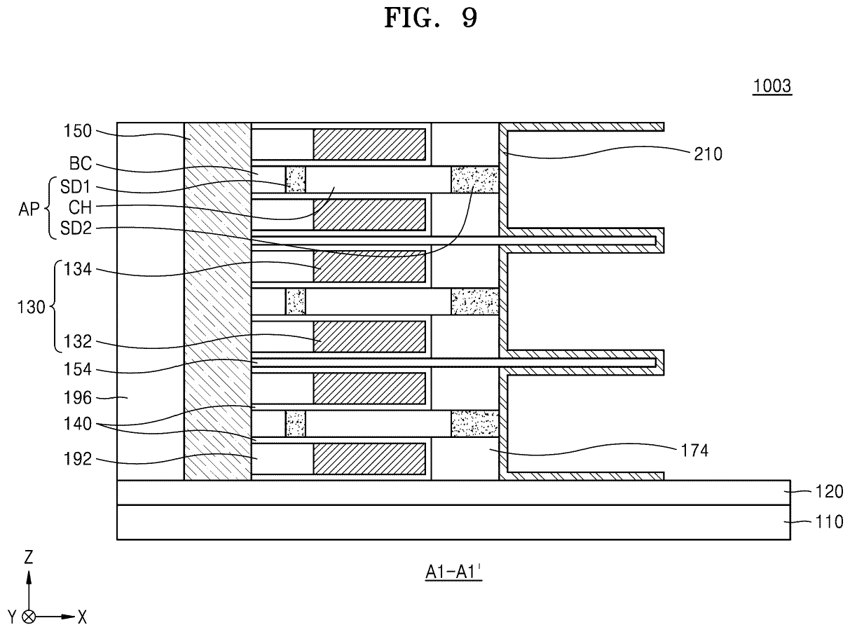

Referring to FIG. 9, a stacked structure 1003 may be formed by depositing the first electrode 210 on surfaces of the spacer buried layer 174, the second source/drain region SD2, and the interlayer isolation insulating layer 154 in the stacked structure 1002 of FIG. 8. The first electrode 210 may cover sidewalls of the spacer buried layer 174 and the second source/drain region SD2 and may cover a surface of a protruding portion of the interlayer separation insulating layer 154 in the first horizontal direction X. According to some embodiments, the first electrode 210 may have a “⊏” shape when viewed in the second horizontal direction Y.

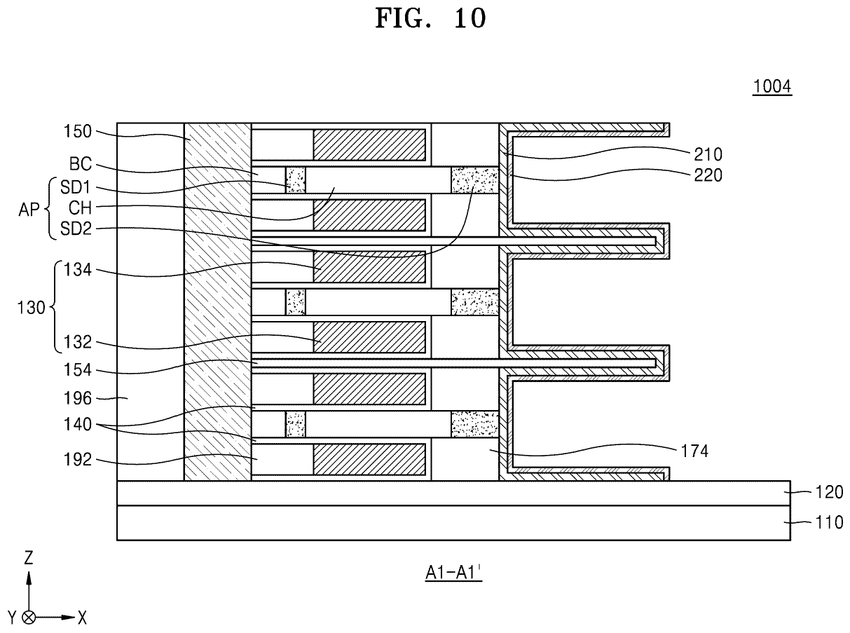

Referring to FIG. 10, a stacked structure 1004 may be formed by depositing the ferroelectric film 220 along the surface of the first electrode 210 in the stacked structure 1003 of FIG. 9. The ferroelectric film 220 may cover the surface of the first electrode 210. According to some embodiments, the ferroelectric film 220 may have substantially the same shape as the first electrode 210.

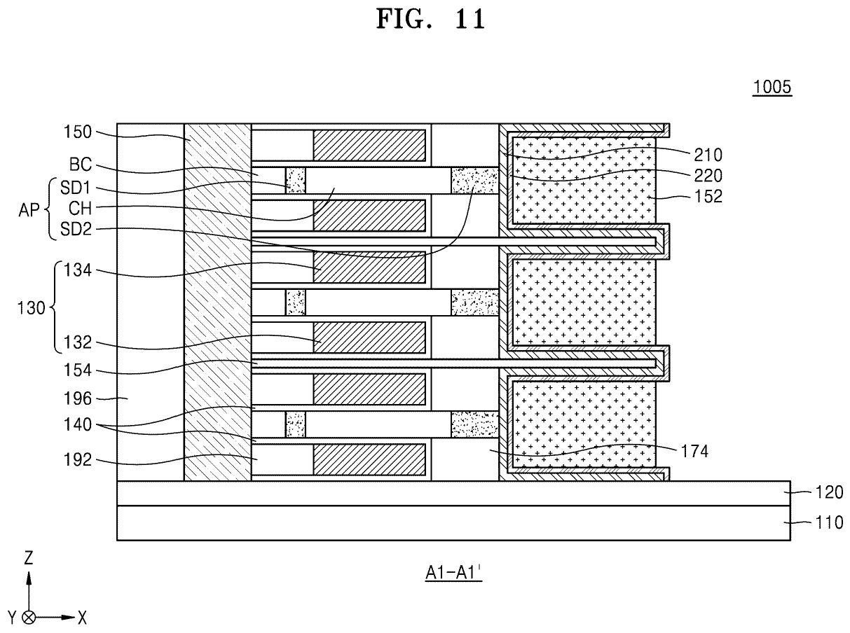

Referring to FIG. 11, a stacked structure 1005 may be formed by depositing a second sacrificial layer 152 into a space formed by the ferroelectric film 220 in the stacked structure 1004 of FIG. 10. A plurality of second sacrificial layers 152 may be provided, and the plurality of second sacrificial layers 152 may be spaced apart from each other in the vertical direction Z. The second sacrificial layer 152 may be spaced apart from the first electrode 210 with the ferroelectric film 220 in between. A side of each of the second sacrificial layers 152 in the first horizontal direction X may protrude or extend less than a side of each of the ferroelectric film 220 and the first electrode 210. That is, the side of each of the ferroelectric film 220 and the first electrode 210 in the first horizontal direction X protrudes further or extends further than the side of each of the second sacrificial layers 152 in the first horizontal direction X.

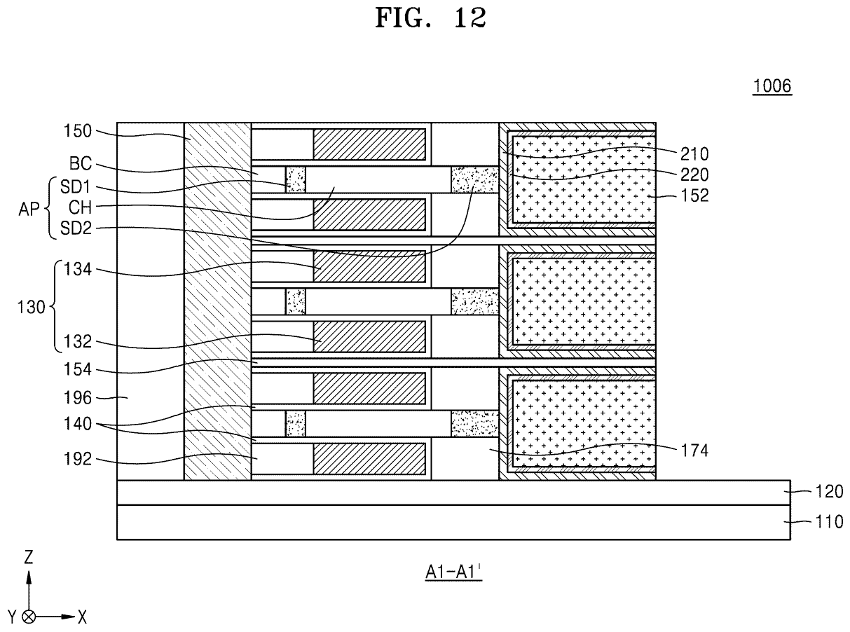

Referring to FIG. 12, a stacked structure 1006 may be formed by etching the ferroelectric film 220 and the first electrode 210 in the stacked structure 1005 of FIG. 11. According to some embodiments, due to the etching process, a horizontal level of the side of each of the ferroelectric film 220 and the first electrode 210 in the first horizontal direction X may be the same as a horizontal level of the side of each of the second sacrificial layers 152 in the first horizontal direction X. Due to the etching process, the first electrode 210 may be divided into a plurality of pieces, and the plurality of first electrodes 210 may be spaced apart from each other in the vertical direction Z.

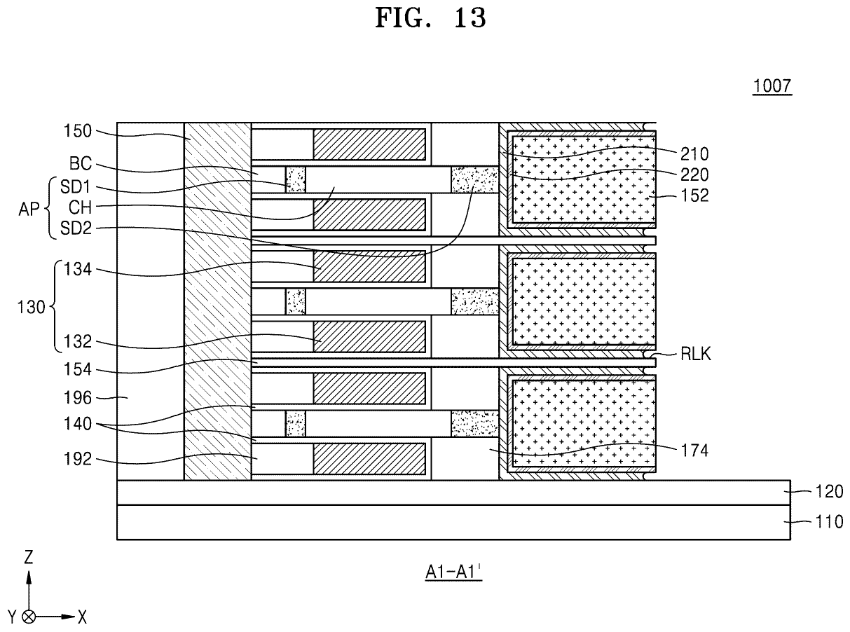

Referring to FIG. 13, a stacked structure 1007 in which a recess RLK is formed by etching the side of the first electrode 210 in the first horizontal direction X exposed to the outside in the stacked structure 1006 of FIG. 12 may be provided. A virtual cross-section of the recess RLK in the X-Z plane may be in the shape of a semicircle or a semi-ellipse. According to some embodiments, each of the plurality of first electrodes 210 may have two recesses RLK.

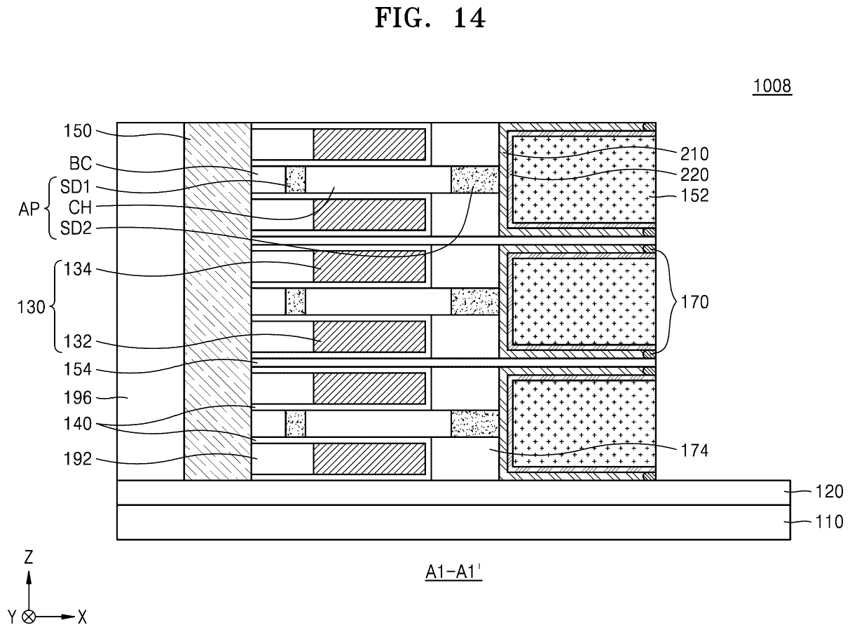

Referring to FIG. 14, a stacked structure 1008 may be provided by forming leakers 170 at the recesses RLK in the stacked structure 1007 of FIG. 13. The leaker 170 may be formed by filling the recess RLK. A virtual cross-section of the leaker 170 in the X-Z plane may be in the shape of a semicircle or a semi-ellipse.

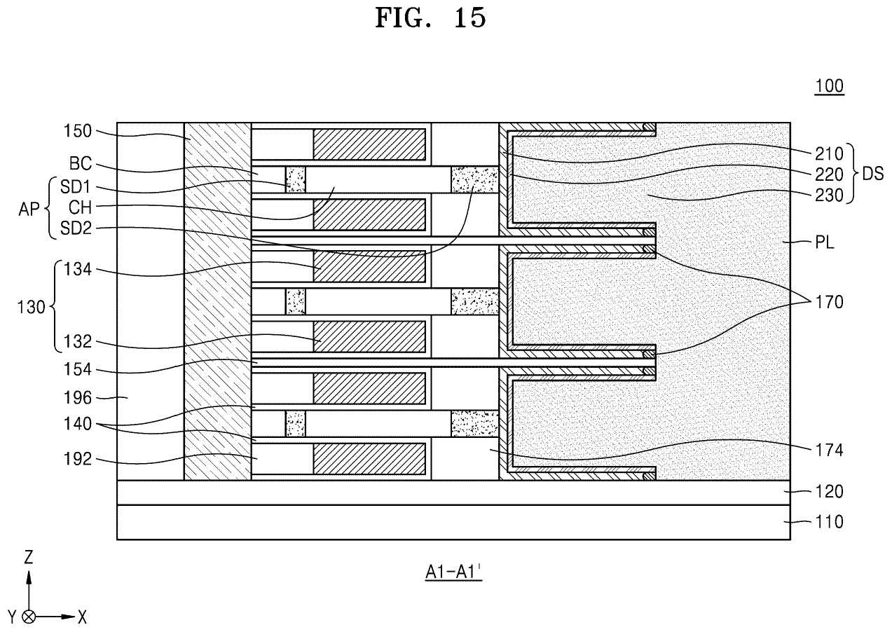

Referring to FIG. 15, a semiconductor memory device 100 may be formed by removing the second sacrificial layer 152 from the stacked structure 1008 in FIG. 14 and forming the second sacrificial layer 152 and the plate line PL covering the second sacrificial layer 152. The plate line PL may be in contact with the leaker 170 in the first horizontal direction X.

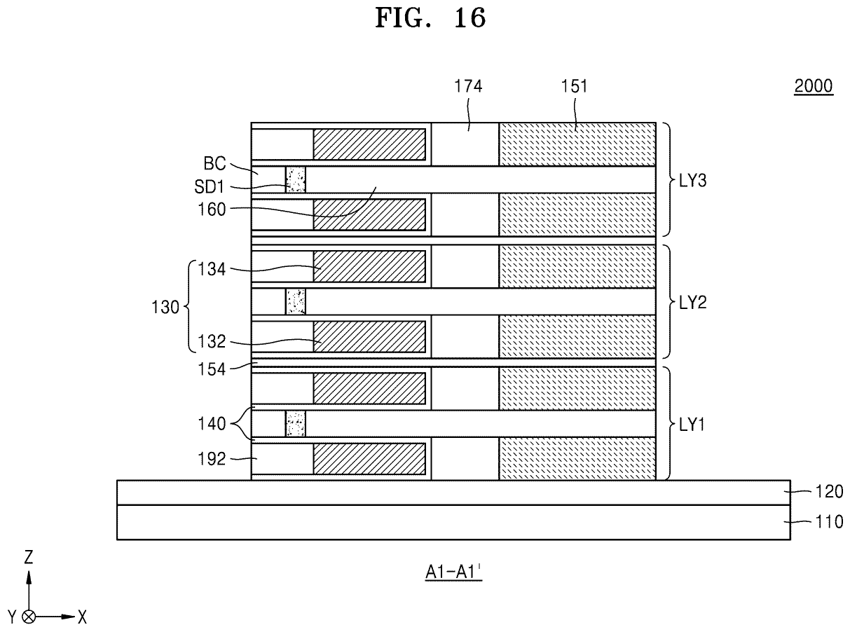

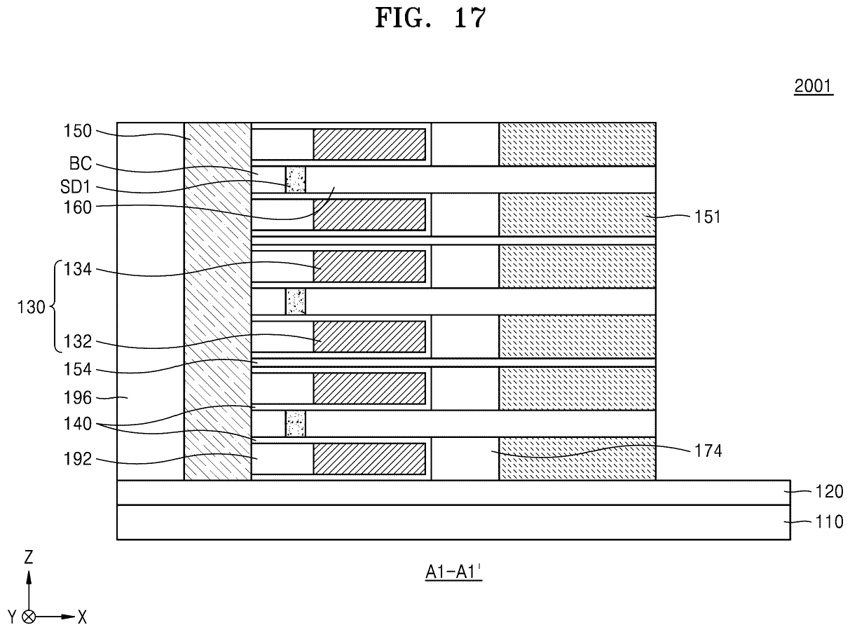

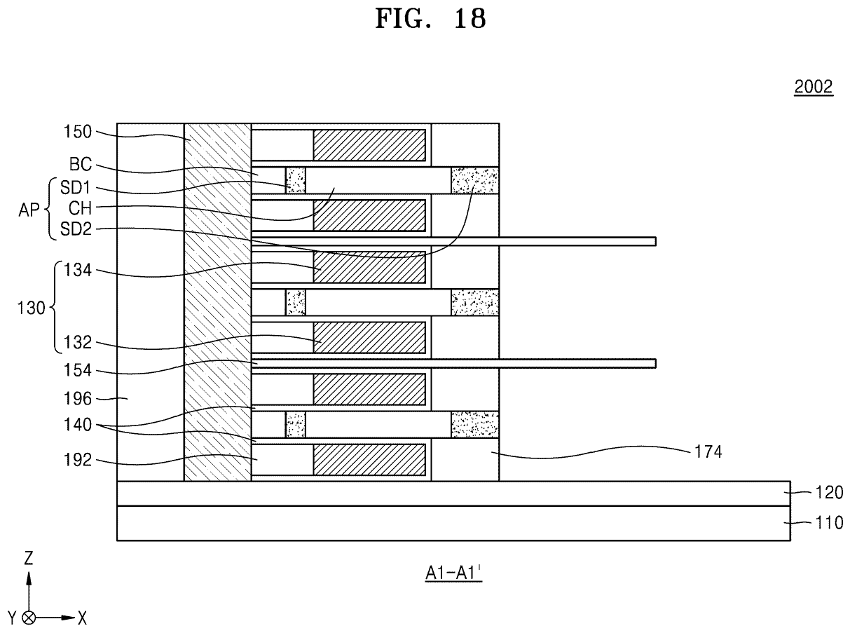

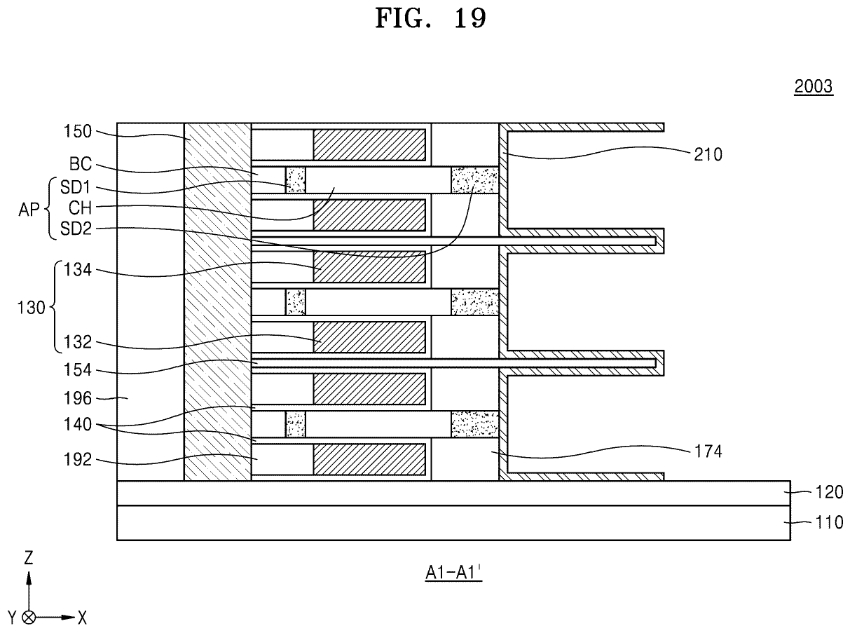

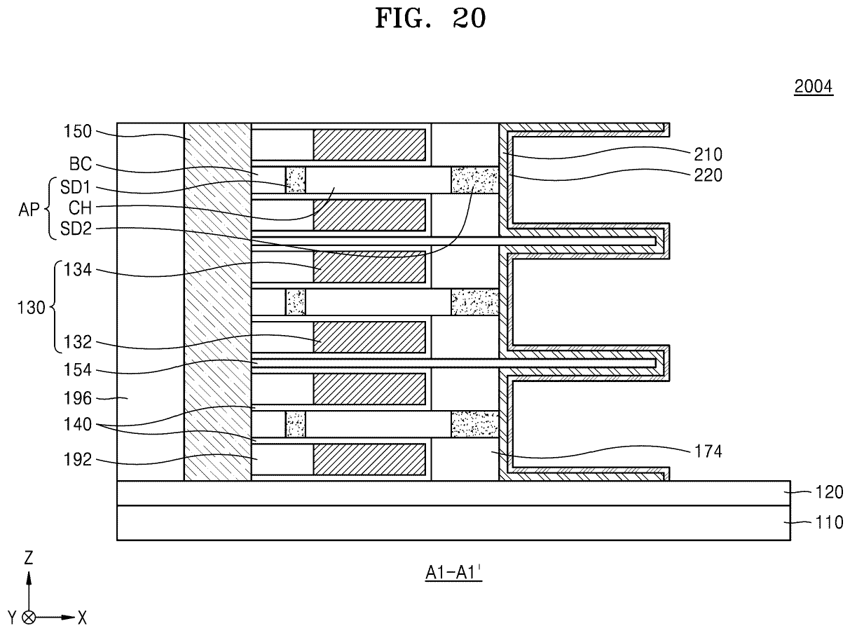

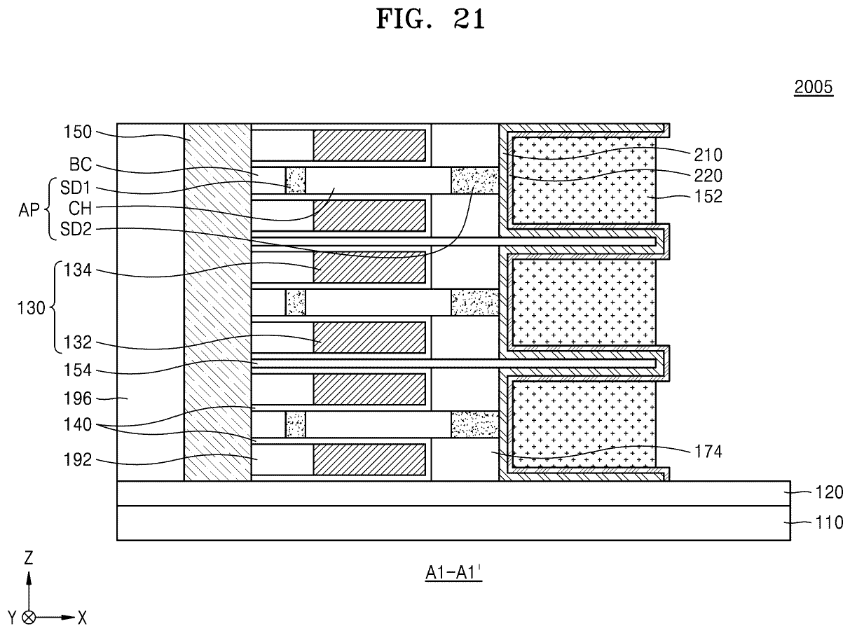

FIGS. 16 to 25 are cross-sectional views schematically showing a method of manufacturing the semiconductor memory device of FIG. 5. Hereinafter, description that is substantially the same as that given with reference to FIGS. 2 to 15 is omitted and the differences therebetween are mainly described. Additionally, since FIGS. 16 to 22 are substantially the same as or similar to FIGS. 6 to 12, repeated description thereof is omitted here in the interest of brevity.

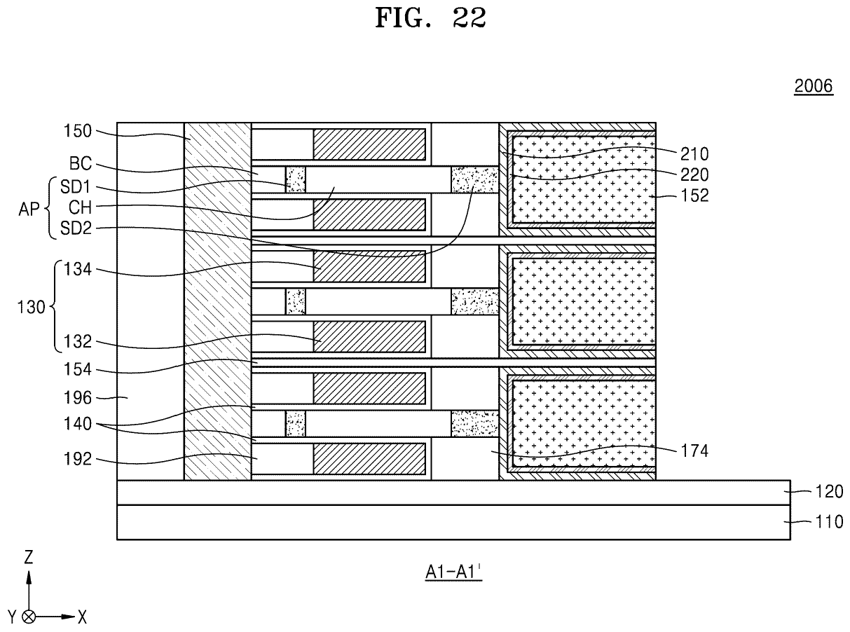

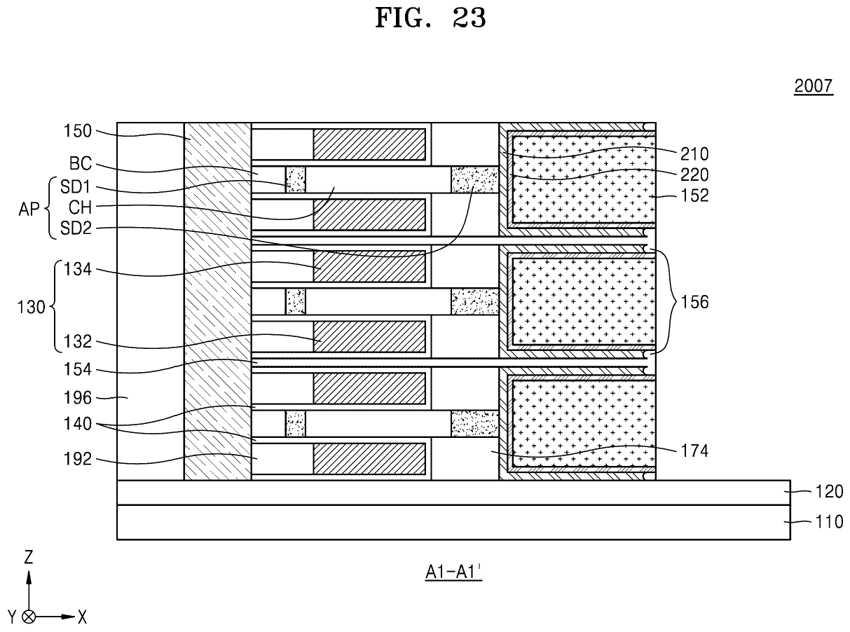

Referring to FIG. 23, a stacked structure 2007 may be provided by etching the side of the first electrode 210 in the first horizontal direction X exposed to the outside in the stacked structure 2006 of FIG. 22, and forming the electrode separation insulating layer 156 in the etched region. The electrode separation insulating layer 156 may penetrate or extend through the first electrode 210 in the first horizontal direction X. According to some embodiments, the electrode separation insulating layer 156 may be formed on each of upper and lower ends of the interlayer separation insulating layer 154 in the first horizontal direction X. A cross-section of the electrode separation insulating layer 156 in the X-Z plane may be in the shape of a semicircle or a semi-ellipse.

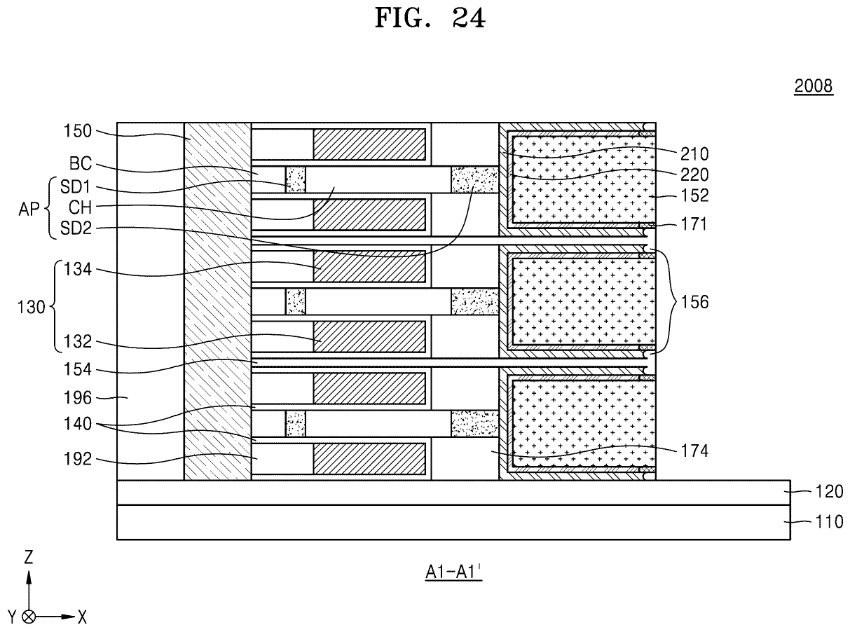

Referring to FIG. 24, a stacked structure 2008 may be provided by etching the side of the ferroelectric film 220 exposed to the outside in the first horizontal direction X in the stacked structure 2007, and filling the etched region with the leaker 171. The leaker 171 may be in contact with the electrode separation insulating layer 156 in the vertical direction Z. A cross-section of the leaker 171 in the X-Z plane may be in the shape of a semicircle or a semi-ellipse.

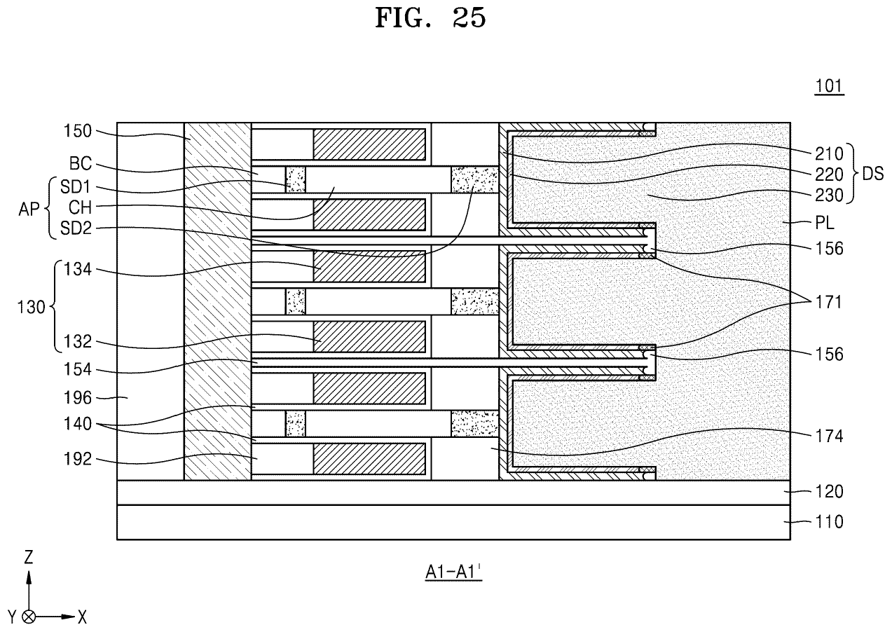

Referring to FIG. 25, a semiconductor memory device 101 may be formed by removing the second sacrificial layer 152 from the stacked structure 2008 of FIG. 24, and forming the second electrode 230 and the plate line PL covering the second electrode 230. The plate line PL may be in contact with the leaker 171 in the first horizontal direction X, and the second electrode 230 may be in contact with the leaker 171 in the vertical direction Z.

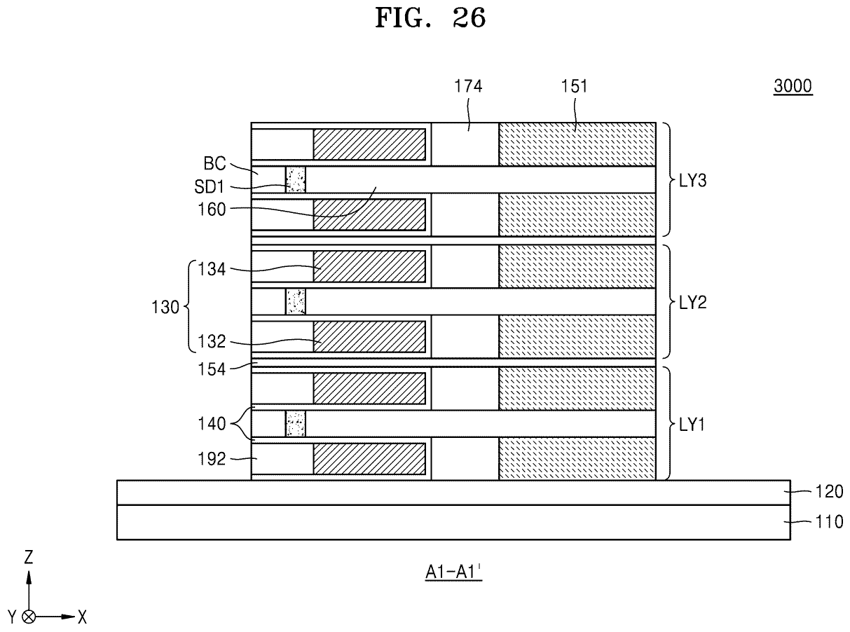

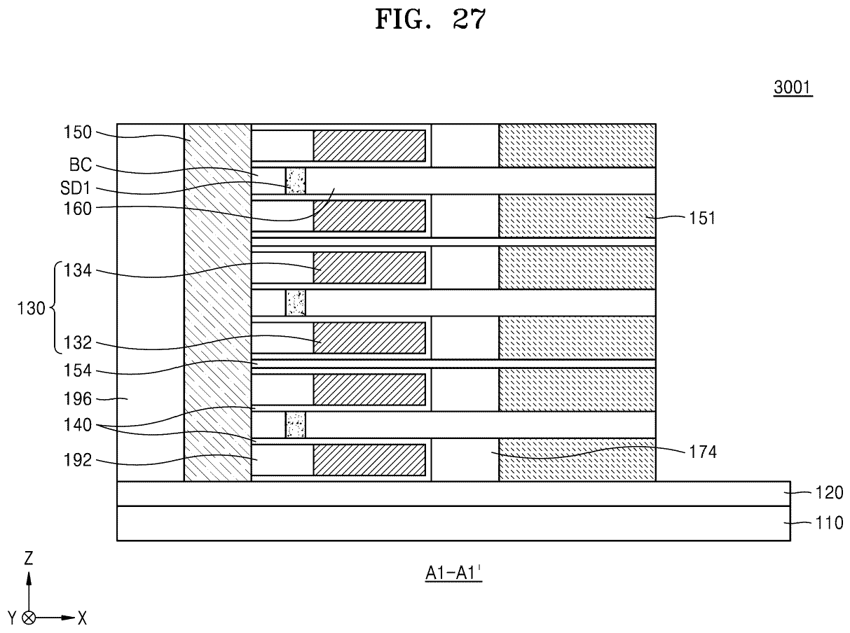

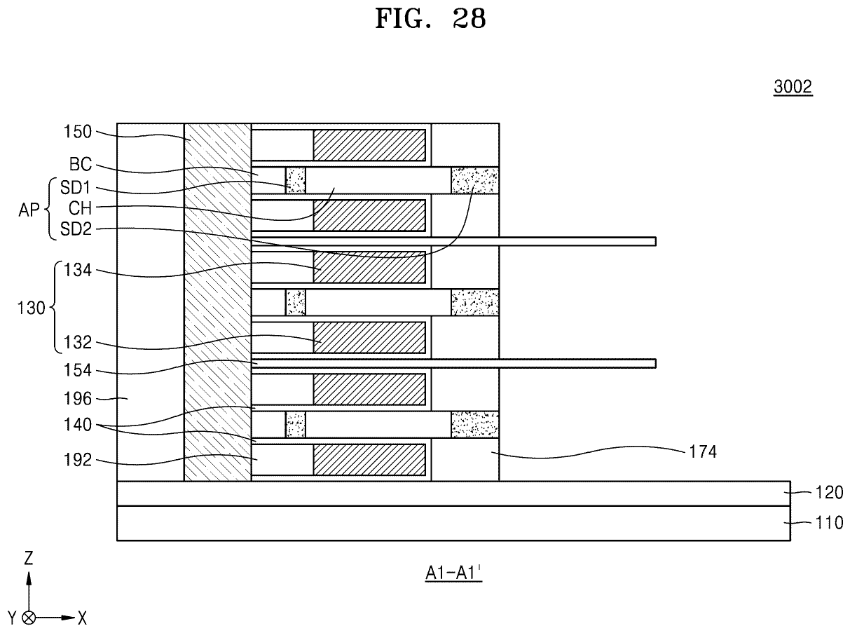

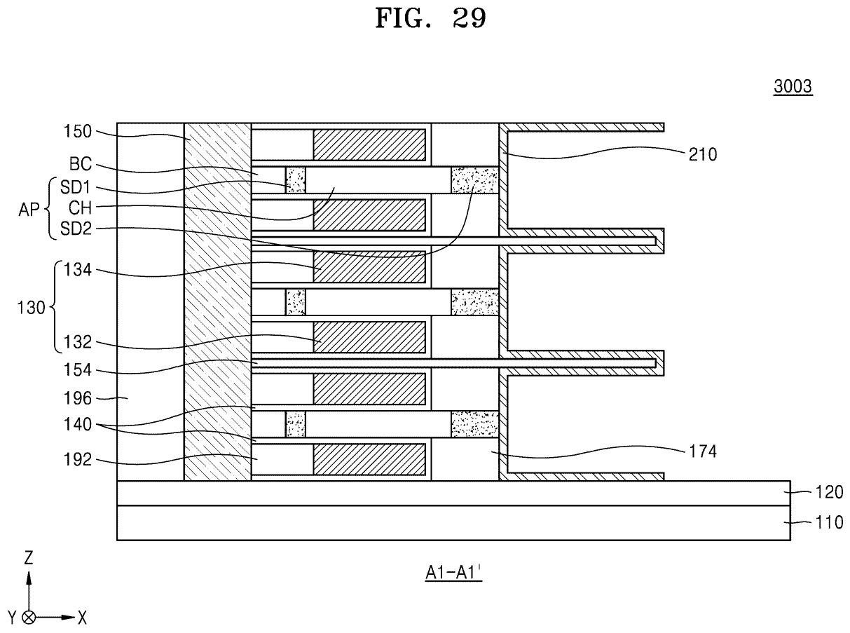

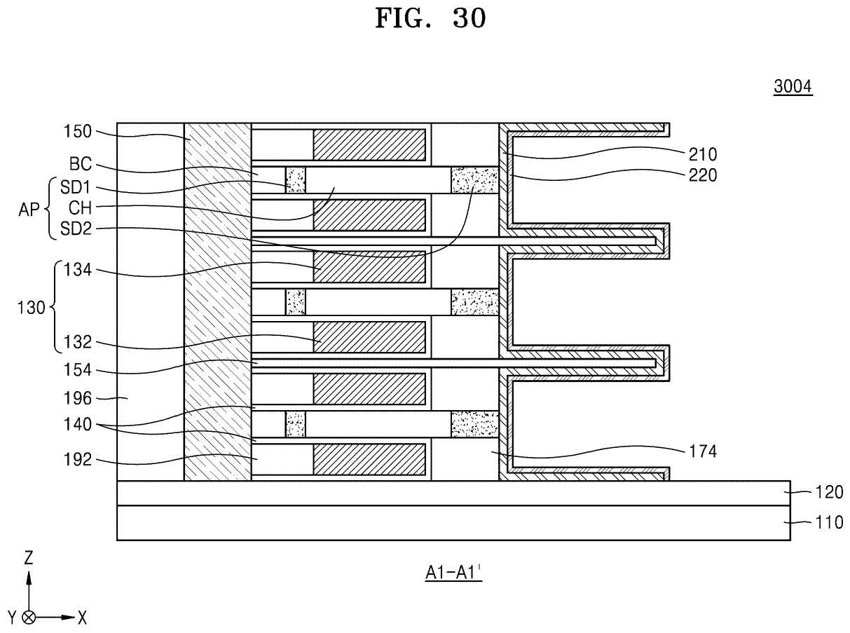

FIGS. 26 to 35 are cross-sectional views schematically showing a method of manufacturing the semiconductor memory device of FIG. 5. Hereinafter, description that is substantially the same as that given with reference to FIGS. 2 to 25 may be substantially omitted and only the differences therebetween are mainly described. Additionally, since FIGS. 26 to 31 are substantially the same as or similar to FIGS. 16 to 21, substantial description thereof is omitted here in favor of the above in the interest of brevity.

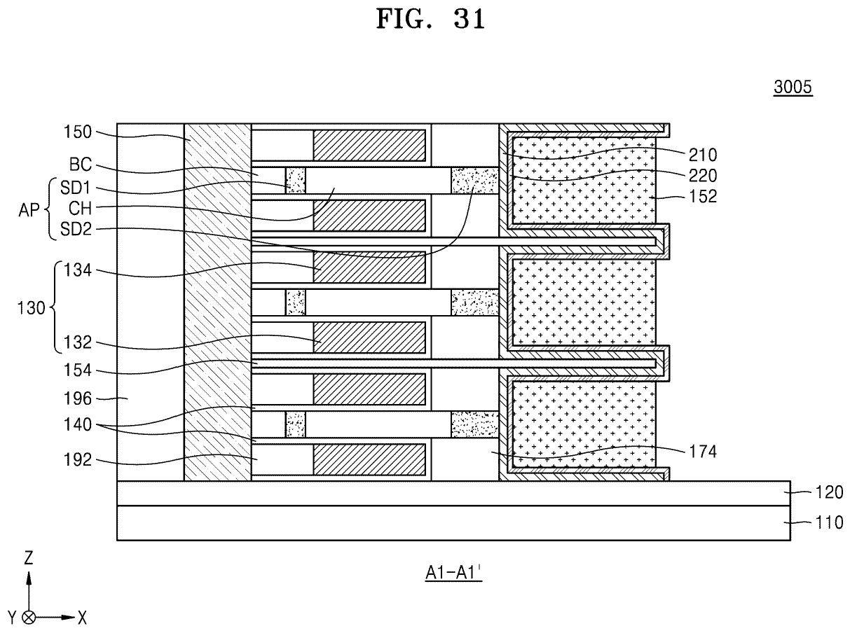

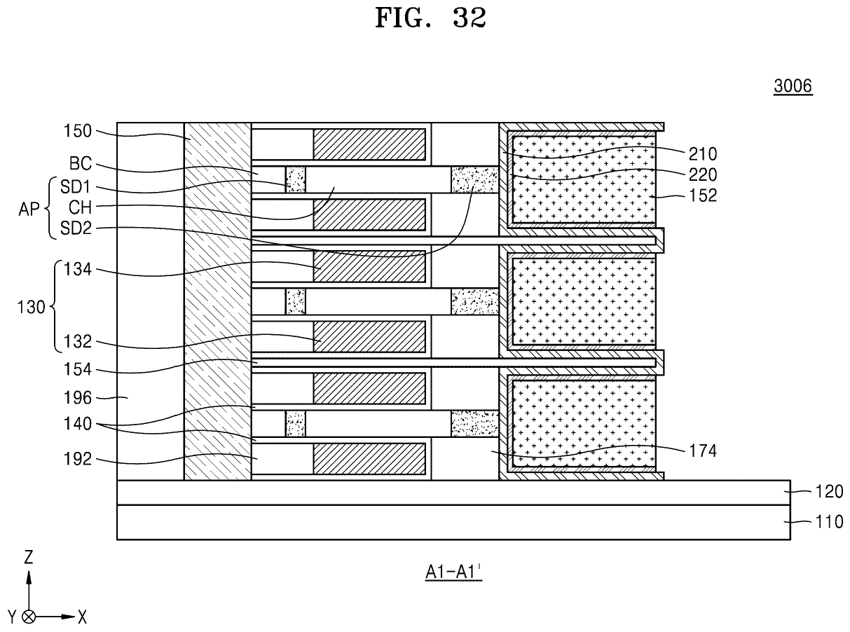

Referring to FIG. 32, a stacked structure 3006 may be formed by etching the ferroelectric film 220 in the stacked structure 3005 of FIG. 31. Due to the etching process, the side of the ferroelectric film 220 in the first horizontal direction X may be positioned at the same horizontal level as the side of the second sacrificial layer 152 in the first horizontal direction X. The first electrode 210 may protrude further in the first horizontal direction X than the ferroelectric film 220 and the second sacrificial layer 152.

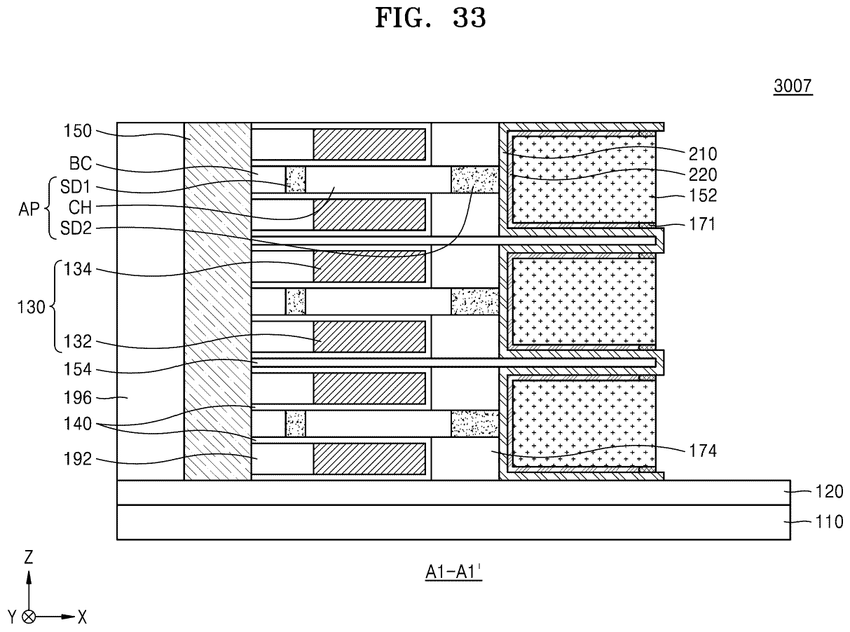

Referring to FIG. 33, a stacked structure 3007 may be provided by etching the side of the ferroelectric film 220 in the first horizontal direction X exposed to the outside in the stacked structure 3006 of FIG. 32, and filling the etched region with the leaker 171. The leaker 171 may be in contact with the first electrode 210 in the vertical direction Z.

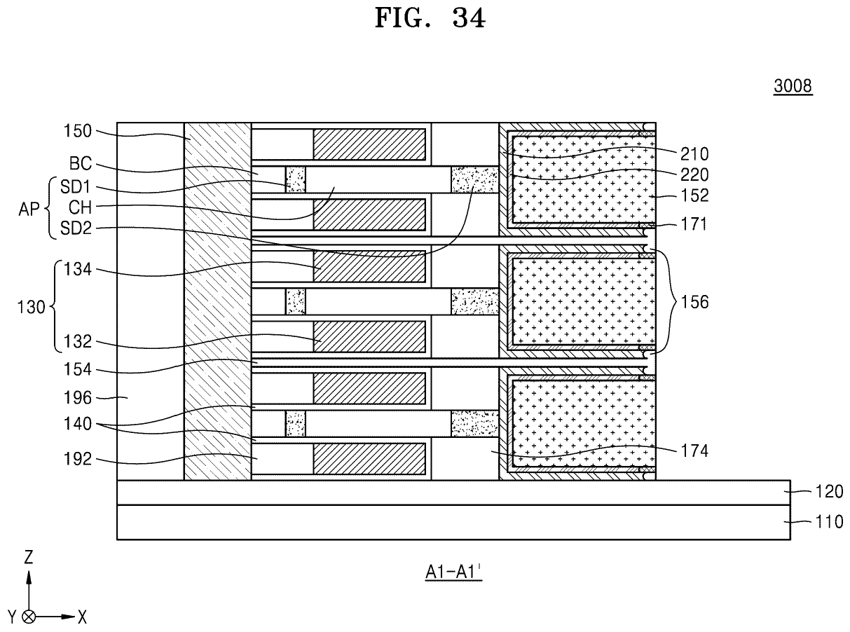

Referring to FIG. 34, a stacked structure 3008 may be provided by etching the first electrode 210 in the stacked structure 3007 of FIG. 33, and forming the electrode separation insulating layer 156. By etching the portion of the first electrode 210 that protrudes further in the first horizontal direction X than the second sacrificial layer 152, the side of the first electrode 210 in the first horizontal direction X is positioned at the same horizontal level as the side of the second sacrificial layer 152 in the first horizontal direction X. Thereafter, the side of the first electrode 210 in the first horizontal direction X is etched in the horizontal direction to form a recess, and the recess is filled with the electrode separation insulating layer 156. According to some embodiments, two electrode separation insulating layers 156 may be formed for each first electrode 210.

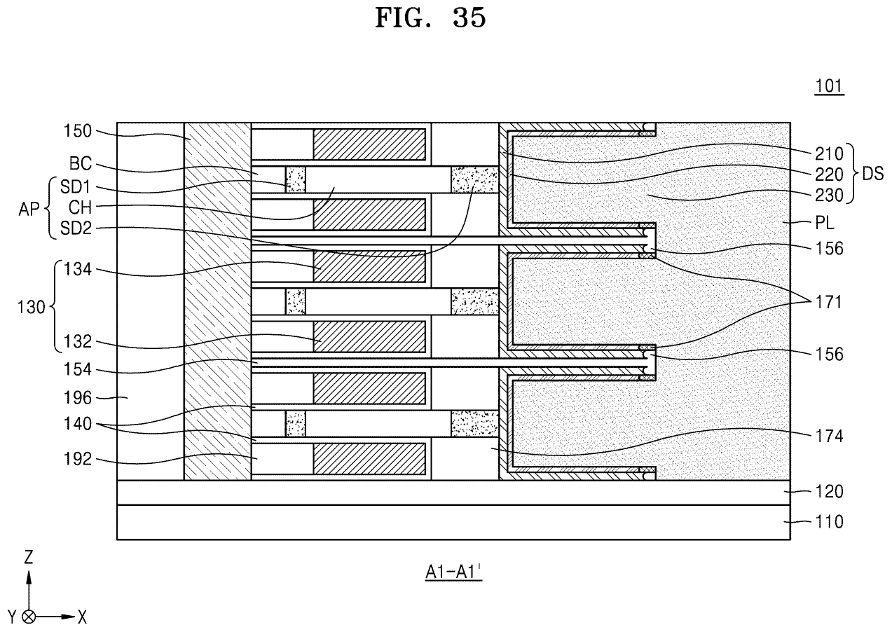

Referring to FIG. 35, a semiconductor memory device 101 may be formed by removing the second sacrificial layer 152 from the stacked structure 3008 of FIG. 34, and forming the second electrode 230 and the plate line PL covering the second electrode 230. The plate line PL may be in contact with the leaker 171 in the first horizontal direction X, and the second electrode 230 may be in contact with the leaker 171 in the vertical direction Z.

While the inventive concepts have been particularly shown and described with reference to some examples of embodiments thereof, it will be understood that various changes in form and details may be made therein without departing from the scope of the following claims.

What is claimed is:

1. A semiconductor memory device comprising:
a plurality of semiconductor patterns that extend in a first horizontal direction on a substrate and having a first source/drain region, a channel region, and a second source/drain region arranged in the first horizontal direction;
at least one interlayer separation insulating layer that separates the plurality of semiconductor patterns from each other in a vertical direction that is perpendicular to the first horizontal direction;
a plurality of word lines each surrounding the channel region of each of the plurality of semiconductor patterns;
a bit line connected to the first source/drain region of each of the plurality of semiconductor patterns and extending in the vertical direction;
a plurality of first electrodes each on a first side of the second source/drain region of each of the plurality of semiconductor patterns;
a plurality of second electrodes each positioned inside a respective one of the plurality of first electrodes;
a ferroelectric film positioned between the first electrode and the second electrode;
a plate line that contacts the plurality of second electrodes and extends in the vertical direction; and
a leaker configured to transfer charge between the first electrode and the second electrode.

2. The semiconductor memory device of claim 1, wherein the leaker is located between the first electrode and the plate line.

3. The semiconductor memory device of claim 2, wherein a cross-section of the leaker in a plane is in the shape of a semicircle, and the semicircle has a curvature portion facing the first electrode and a straight portion facing the plate line.

4. The semiconductor memory device of claim 2, wherein an area where the leaker is in contact with the first electrode is greater than an area where the leaker is in contact with the plate line.

5. The semiconductor memory device of claim 1, wherein the leaker is located between the ferroelectric film and the plate line.

6. The semiconductor memory device of claim 5, wherein an electrode separation insulating layer is positioned between the first electrode and the plate line, and wherein the electrode separation insulating layer separates the first electrode from the plate line in the first horizontal direction.

7. The semiconductor memory device of claim 5, wherein a cross-section of the leaker in a plane is in the shape of a semicircle, and the semicircle has a curvature portion facing the ferroelectric film and a straight portion facing the plate line.

8. The semiconductor memory device of claim 5, wherein the sum of an area where the leaker is in contact with the second electrode and an area where the leaker is in contact with the plate line is greater than an area where the leaker is in contact with the first electrode.

9. The semiconductor memory device of claim 1, wherein the interlayer separation insulating layer is in contact with the plate line in the first horizontal direction.

10. The semiconductor memory device of claim 1, wherein the leaker comprises at least one of amorphous silicon, polycrystalline silicon, germanium, chalcogen compound, silicon nitride, or silicon oxide.

11. The semiconductor memory device of claim 1, wherein the leaker comprises a material doped with at least one metal selected from among titanium, tantalum, niobium, molybdenum, strontium, yttrium, chromium, hafnium, zirconium, meitnerium, and lanthanum.

12. A semiconductor memory device comprising:
a plurality of semiconductor patterns extending in a first horizontal direction on a substrate and having a first source/drain region, a channel region, and a second source/drain region arranged in the first horizontal direction;
at least one interlayer separation insulating layer that separates the plurality of semiconductor patterns from each other in a vertical direction that is perpendicular to the first horizontal direction;
a plurality of word lines each surrounding the channel region of each of the plurality of semiconductor patterns;
a bit line connected to the first source/drain region of each of the plurality of semiconductor patterns and extending in the vertical direction;
a plurality of first electrodes each disposed on one side of the second source/drain region of each of the plurality of semiconductor patterns;
a plurality of second electrodes each positioned inside a respective one of the plurality of first electrodes;
a ferroelectric film positioned between the first electrode and the second electrode;
a plate line that contacts the plurality of second electrodes and extends in the vertical direction; and
a leaker configured to transfer charge between the first electrode and the second electrode;
wherein the interlayer separation insulating layer is in contact with the plate line in the first horizontal direction, and
a cross-section of the leaker in a plane is in the shape of a semicircle, and the semicircle has a curvature portion facing the ferroelectric film and a straight portion facing the plate line.

13. The semiconductor memory device of claim 12, wherein the leaker is positioned between the first electrode and the plate line.

14. The semiconductor memory device of claim 13, wherein an area where the leaker is in contact with the first electrode is greater than an area where the leaker is in contact with the plate line.

15. The semiconductor memory device of claim 12, wherein the leaker is located between the ferroelectric film and the plate line.

16. The semiconductor memory device of claim 15, wherein an electrode separation insulating layer is positioned between the first electrode and the plate line, and wherein the electrode separation insulating layer separates the first electrode from the plate line in the first horizontal direction.

17. The semiconductor memory device of claim 15, wherein the sum of an area where the leaker is in contact with the second electrode and an area where the leaker is in contact with the plate line is greater than an area where the leaker is in contact with the first electrode.

18. A semiconductor memory device comprising:
a plurality of semiconductor patterns extending in a first horizontal direction on a substrate and having a first source/drain region, a channel region, and a second source/drain region arranged in the first horizontal direction;
at least one interlayer separation insulating layer that separates the plurality of semiconductor patterns from each other in a vertical direction that is perpendicular to the first horizontal direction;
a plurality of word lines each surrounding the channel region of each of the plurality of semiconductor patterns;
a gate dielectric film surrounding the word lines;
a contact layer connected to the first source/drain region of each of the plurality of semiconductor patterns;
a bit line that contacts the contact layer in the first horizontal direction and extends in the vertical direction;
a plurality of first electrodes each on one side of the second source/drain region of each of the plurality of semiconductor patterns;
a plurality of second electrodes each positioned inside respective ones of the plurality of first electrodes;
a ferroelectric film positioned between the first electrode and the second electrode;
a plate line that contacts the plurality of second electrodes and extends in the vertical direction; and
a leaker configured to transfer charge between the first electrode and the second electrode;
wherein the interlayer separation insulating layer is in contact with the plate line in the first horizontal direction,
wherein the leaker comprises at least one of amorphous silicon, polycrystalline silicon, germanium, chalcogen compound, silicon nitride, and silicon oxide,
wherein the leaker is located between the first electrode and the plate line, and an area where the leaker is in contact with the first electrode is greater than an area where the leaker is in contact with the plate line, and
wherein a cross-section of the leaker in a plane is in the shape of a semicircle.

19. The semiconductor memory device of claim 18, wherein the semicircle has a curvature portion facing the ferroelectric film and a straight portion facing the plate line.

20. The semiconductor memory device of claim 18, wherein the leaker comprises a material doped with at least one metal selected from among titanium, tantalum, niobium, molybdenum, strontium, yttrium, chromium, hafnium, zirconium, meitnerium, and lanthanum.
